(19) United States
(12) Patent Application Publication
(10) Pub. No.: US 2024/0211660 A1
(43) Pub. Date: Jun. 27, 2024

(54) SYSTEMS AND METHODS FOR ANTENNA DESIGN

(71) Applicant: Meta Platforms Technologies, LLC, Menlo Park, CA (US)

(72) Inventors: Weiping Dou, Cupertino, CA (US); Yuandong Tian, San Carlos, CA (US); Andrew Cohen, San Francisco, CA (US); Jiang Zhu, Cupertino, CA (US); Geng Ye, Union City, CA (US); Ulf Jan Ove Mattsson, Campbell, CA (US); Peter Eli Renner, San Jose, CA (US); Beidi Chen, Pittsburgh, PA (US); Xiaomeng Yang, Sunnyvale, CA (US); Kevin Stone, San Luis Obispo, CA (US); Slawomir Marcin Koziel, Kopavogur (IS)

(21) Appl. No.: 18/392,965

(22) Filed: Dec. 21, 2023

Related U.S. Application Data
(60) Provisional application No. 63/476,608, filed on Dec. 21, 2022.

(51) Int. Cl. G06F 30/27

(52) U.S. Cl. CPC G06F 30/27

(57) ABSTRACT

The disclosed computer-implemented method may include generating, using a machine-learning model of a computing device, a set of antenna designs. The method may also include tokenizing, by the computing device, each antenna design in the generated set of antenna designs. Additionally, the method may include predicting, by the machine-learning model of the computing device, a frequency response for each tokenized antenna design. Furthermore, the method may include comparing, by the computing device, the frequency response for each tokenized antenna design. Finally, the method may include selecting, by the computing device based on the comparison, an antenna design that meets a performance threshold for the frequency response. Various other methods, systems, and computer-readable media are also disclosed.

### CROSS REFERENCE TO RELATED APPLICATION

This application claims the benefit of U.S. Provisional Application No. 63/476,608, filed 21 Dec. 2022, the disclosure of which is incorporated, in its entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a flow diagram of an exemplary method for antenna design.

FIG. 2 is a block diagram of an exemplary system for antenna design.

FIG. 3 is an illustration of exemplary channels of image representation of an exemplary antenna design.

FIG. 4 is a block diagram of an exemplary method to determine a frequency response for an exemplary antenna design.

FIG. 5 is a block diagram of an exemplary method of tokenizing an exemplary antenna design.

FIG. 6 is a block diagram of an exemplary method to determine exemplary global characteristics based on exemplary visual tokens.

FIG. 7 is an illustration of exemplary augmented-reality glasses that may be used in connection with embodiments of this disclosure.

FIG. 8 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Antennas are used in electronics to send and receive various types of signals. The design and creation of antennas often needs to account for spatial relationships between various electronic components as well as interference of signals. As the demand for broader frequency bandwidth coverage increases, especially for artificial or virtual reality devices, the need for more complex antenna design also increases. To design antennas, simulations may be used to test various parameters prior to physically building an antenna. For example, simulation software may create a full three-dimensional (3D) model of a device that incorporates an antenna and may test the use of the antenna. However, this type of simulation may be costly to create and test each individual design. Designs are often tested one at a time, with changes made after each simulation, and a single design may take days to fully model and test. For complex devices or computing systems, such as artificial or virtual reality systems, hundreds of simulations may be performed to find an optimal antenna design that complies with all the different parameters. For wearable devices, these parameters may be even more constrained by weight and size limits.

Traditional methods for virtual simulation and design of antennas may be a highly non-linear problem that may require a sequential process. Typical commercial simulation software may be computationally intensive and slow to test large numbers of designs. This creates a bottleneck in the time taken to simulate and test new iterations of a design, thereby making it harder to test multiple design iterations quickly to find an optimal design. Sequential iterations of design can use the results of one test to generate the next iteration, but this also slows the process. Physical designs may be even more sensitive to small changes and more costly in terms of both money and time.

Some design processes may attempt to simulate mesh representations of antennas. However, mesh representations are typically high-resolution, which results in costly computation. Other methods may attempt to use a coarse, approximate physics-driver simulation to model designs, but the data or examples used in these methods can be costly to create or collect. Thus, better methods of automating antenna design and testing are needed to avoid the costly process of testing while ensuring antennas meet signal requirements.

The present disclosure is generally directed to systems and methods for antenna design. As will be explained in greater detail below, embodiments of the present disclosure may, by deriving a surrogate model using machine-learning methods, increase the efficiency of antenna computation and design. By training a machine-learning model on image representations of antenna designs, the systems and methods described herein may automate the generation of new designs that fulfill basic requirements. For example, the disclosed systems and methods may generate designs that appear to represent patches of metallic substrate on a printed circuit board of a specified size. Additionally, the disclosed systems and methods may use a neural network model as part of the machine learning to computationally learn the features of the antenna designs. The disclosed systems and methods may then perform additional spatial attention processes to create visual tokens for each generated antenna design. For example, by applying convolution and a softmax function to feature maps, spatial attention can better interpret visual images through deep learning. The systems and methods disclosed herein may then apply transformer network architecture to the visual tokens.

By implementing a transformer-based encoder to handle the non-linear relationship between antenna topology and resonances, the disclosed systems and methods may enable the disclosed surrogate model to predict local characteristics of each tokenized antenna design. For example, the systems and methods described herein may use the transformer-based encoder to calculate complex zeros and poles for a scattering matrix. Furthermore, the disclosed systems and methods may use the local, spatial components to explain global characteristics. For example, the systems and methods described herein may apply a scattering matrix function to the predicted zeros and poles to calculate a frequency response for a particular antenna design. Finally, the disclose systems and methods may compare the frequency responses of each generated antenna design to determine which design best meets a performance threshold for frequency bandwidth.

In addition, the systems and methods described herein may improve the functioning of a computing device by automating the process of generating and testing new antenna designs and by performing the processes in parallel to improve the speed of testing. These systems and methods may also improve the fields of antenna manufacturing and device design by improving the testing of antennas prior to manufacturing and incorporation into other devices to ensure the antenna meets device requirements. Thus, the disclosed systems and methods may improve over traditional methods of antenna design.

Features from any of the embodiments described herein may be used in combination with one another in accordance with the general principles described herein. These and other embodiments, features, and advantages will be more fully understood upon reading the following detailed description in conjunction with the accompanying drawings and claims.

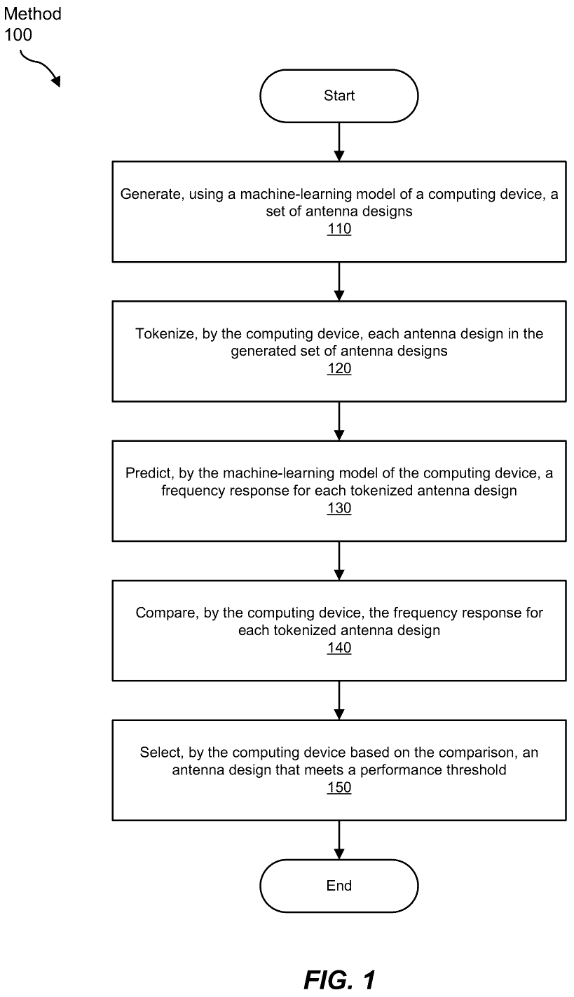

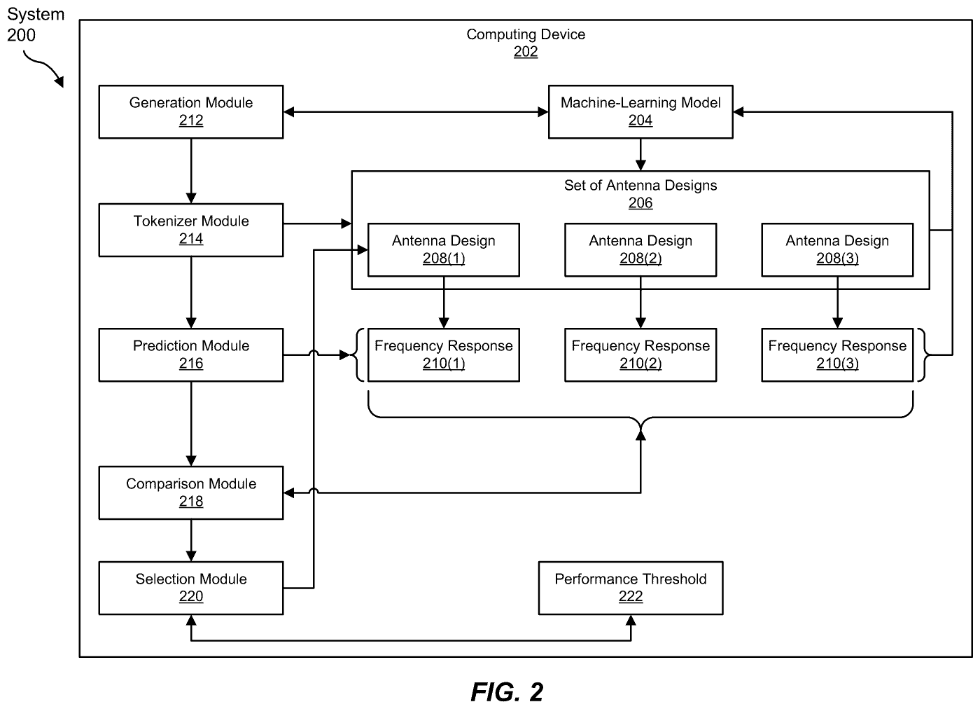

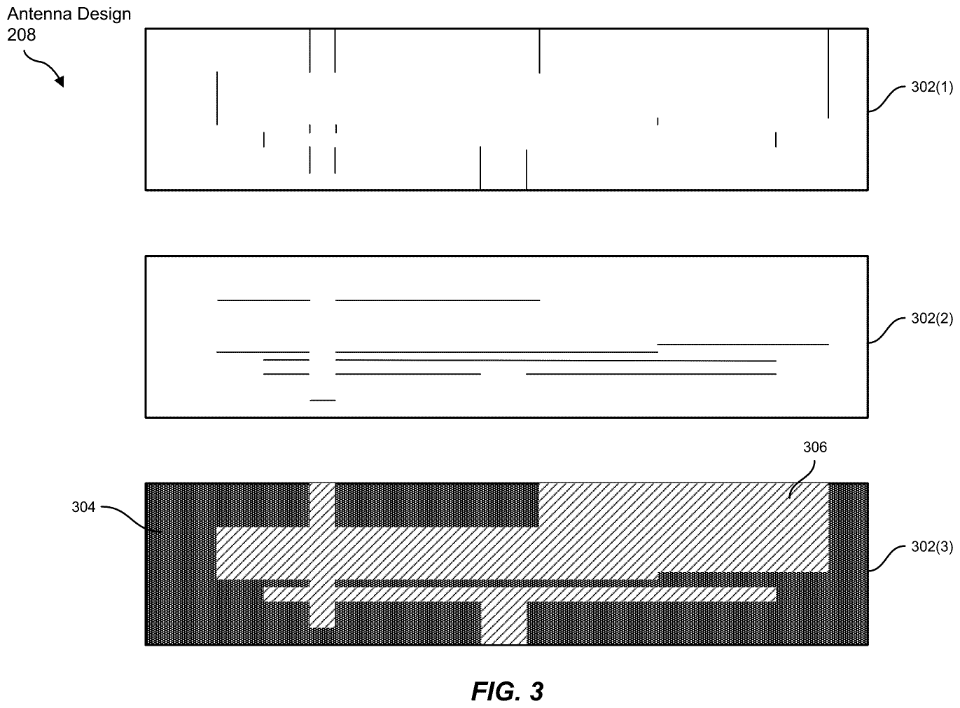

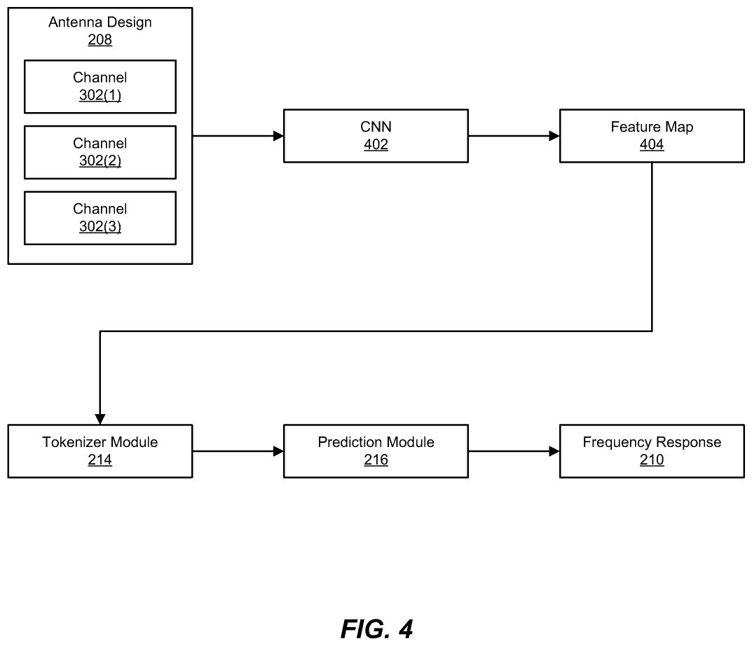

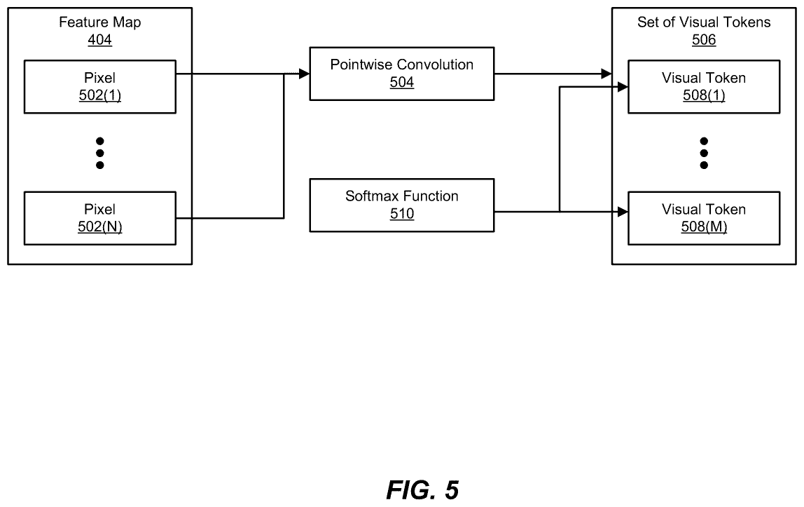

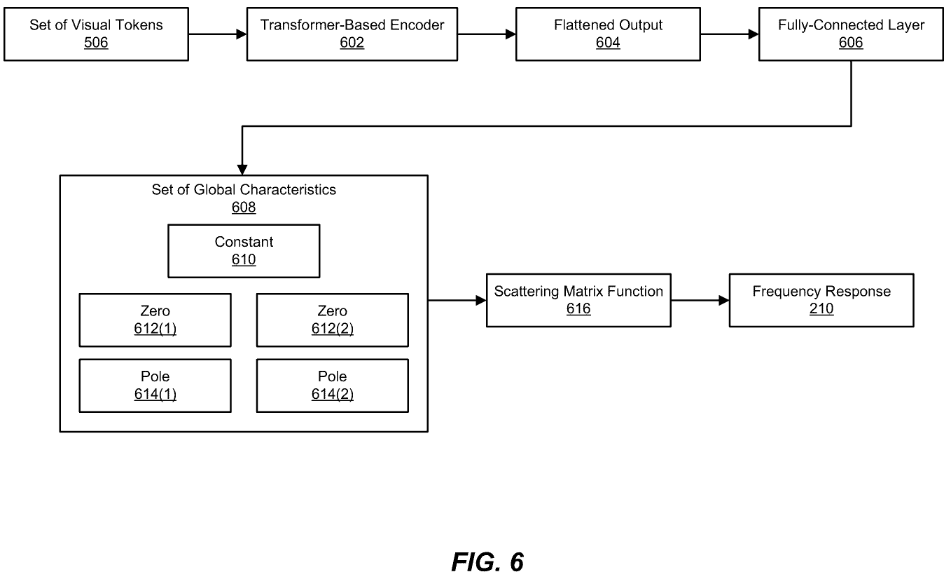

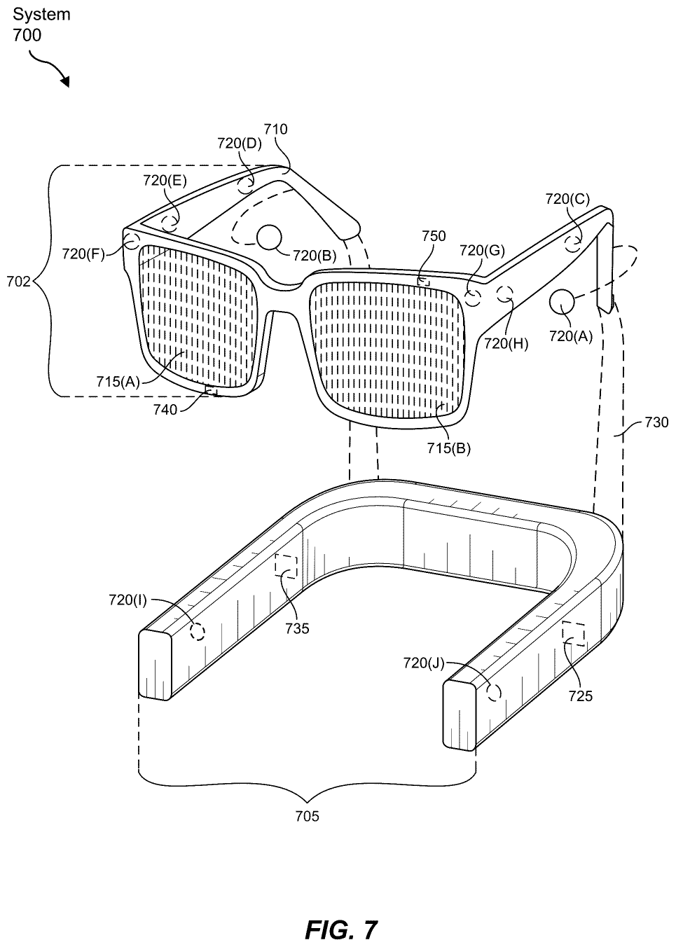

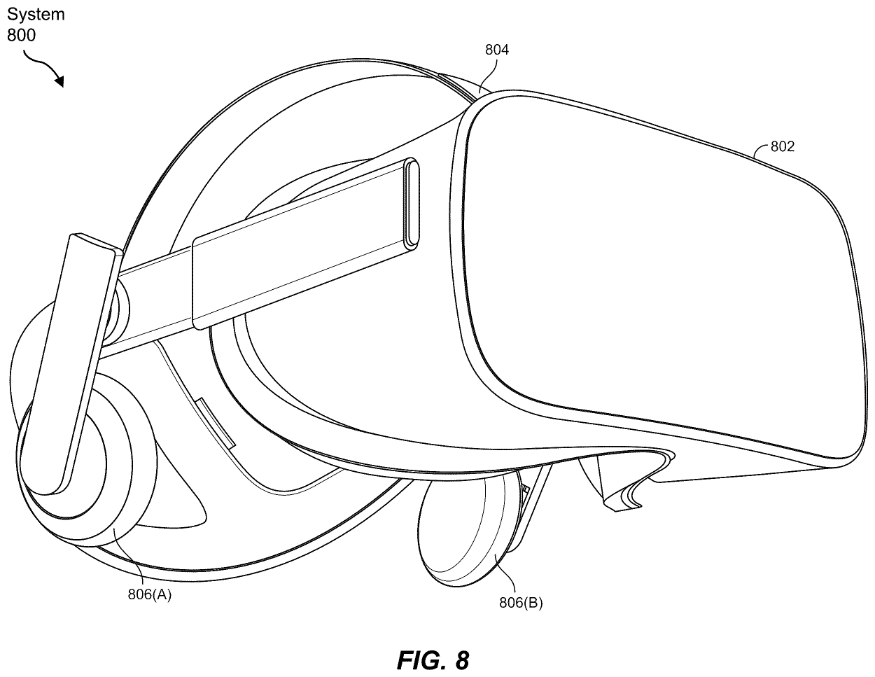

The following will provide, with reference to FIG. 1, detailed descriptions of computer-implemented methods for antenna design. Detailed descriptions of corresponding exemplary systems will be provided in connection with FIG. 2. Detailed descriptions of exemplary channels of image representation of an exemplary antenna design will be provided in connection with FIG. 3. In addition, detailed descriptions of an exemplary method to determine a frequency response for an exemplary antenna design will be provided in connection with FIG. 4. Furthermore, detailed descriptions of an exemplary method of tokenizing an exemplary antenna design will be provided in connection with FIG. 5. Detailed descriptions of an exemplary method to determine exemplary global characteristics based on exemplary visual tokens will be provided in connection with FIG. 6. Finally, detailed descriptions of exemplary augmented-reality glasses and an exemplary virtual-reality headset that may be used in connection with embodiments of this disclosure will be provided in connection with FIGS. 7-8.

FIG. 1 is a flow diagram of an exemplary computer-implemented method 100 for antenna design. The steps shown in FIG. 1 may be performed by any suitable computer-executable code and/or computing system, including the system illustrated in FIG. 2. In one example, each of the steps shown in FIG. 1 may represent an algorithm whose structure includes and/or is represented by multiple sub-steps, examples of which will be provided in greater detail below.

As illustrated in FIG. 1, at step 110 one or more of the systems described herein may generate, using a machine-learning model of a computing device, a set of antenna designs. For example, FIG. 2 is a block diagram of an exemplary system 200 for antenna design. As illustrated in FIG. 2, a generation module 212 may, as part of a computing device 202, generate a set of antenna designs 206 using a machine-learning model 204.

The systems described herein may perform step 110 in a variety of ways. In one example, computing device 202 of FIG. 2 may generally represent any type or form of computing device or server that may be programmed with the modules of FIG. 2 and/or may store all or a portion of the data described herein. For example, computing device 202 may represent a client device capable of storing, generating, and testing antenna designs. In this example, computing device 202 may be programmed with the modules of FIG. 2 to design new antennas for other computing devices and may be capable of reading computer-executable instructions. As another example, computing device 202 may represent a server that is capable of receiving, storing, and/or processing antenna design data for other computing devices. Examples of computing devices may include, without limitation, laptops, tablets, desktops, servers, cellular phones, Personal Digital Assistants (PDAs), multimedia players, embedded systems, wearable devices (e.g., smart watches, smart glasses, etc.), gaming consoles, combinations of one or more of the same, or any other suitable computing device. Additional examples of computing devices may include, without limitation, application servers and database servers configured to provide various database services and/or run certain software applications, such as communication and data transmission services.

In some examples, the term “machine learning” may refer to a computational algorithm that may learn from data in order to make predictions. Examples of machine learning may include, without limitation, support vector machines, neural networks, clustering, decision trees, regression analysis, classification, variations or combinations of one or more of the same, and/or any other suitable supervised, semi-supervised, or unsupervised methods. In these examples, the term “machine-learning model” may refer to a model trained using machine learning techniques to make predictions. In some examples, the term “neural network” may refer to a model of connected data that is weighted based on input data and used to estimate a function. For example, a deep learning neural network may learn from unlabeled data using multiple processing layers in a semi-supervised or unsupervised way.

In some examples, the term “printed circuit board” may refer to a physical board on which computing components may be attached or embedded such that the board provides electrical connections between the computing components. In some examples, the term “substrate” may refer to a layer of a printed circuit board (PCB) or computer chip that acts as a semiconductor, such as a wafer of silicon material. In some examples, the term “antenna” may refer to a computing component capable of transmitting or receiving electromagnetic signals. In some examples, an antenna design may refer to a configuration of conductive substrate material on a PCB. In other examples, an antenna design may refer to a standalone configuration of conductive material.

In one embodiment, set of antenna designs 206 may include, for each antenna design, an image representation of antenna geometry comprising three channels. In some examples, the term “channel” may refer to a component of an image or display, such as color channels or grayscale channels, that defines pixel values. In the example of FIG. 2, set of antenna designs 206 includes antenna designs 208(1)-(3). In this example, each of antenna designs 208(1)-(3) may include a different antenna geometry of a substrate configuration on a PCB. In this example, each PCB may conform to a specific size and shape based on an amount of available space in a computing device for which an antenna is designed. In some embodiments, each of antenna designs 208(1)-(3) may be represented as a two-dimensional (2D) planar antenna that include a PCB or ground plane, a substrate, a discrete port for an input of electrical current, and metallic patches shaped as an antenna. In these embodiments, the generated designs may include different locations of the metallic patches and the discrete port, which may be determined based on previous antenna designs and/or similar computing devices. Additionally, in these embodiments, the topology of the metallic patches may determine a frequency response of an antenna. In some examples, the term “frequency response” may refer to a graph of a signal or voltage gain or loss versus a frequency. In these examples, the frequency response of an antenna design may refer to a range of frequencies to which the antenna is sensitive.

In some embodiments, the three channels of the image representation of antenna geometry may include a representation of boundary values for a first dimension, a representation of boundary values for a second dimension, and a binary image representation of an interior of the antenna geometry. For example, as illustrated in FIG. 3, an antenna design 208 may include channels 302(1)-(3). In this example, channel 302(1) may represent boundary values for an x-direction of the antenna geometry, and channel 302(2) may represent boundary values for a y-direction of the antenna geometry. In this example, channel 302(1) and channel 302(2) may include floating-point numbers to indicate distances between pixels of antenna design 208. In this example, channel 302(3) may represent an image showing patches 306 on a printed circuit board 304 of antenna design 208, represented as binary values. By splitting antenna design 208 into separate channels 302(1)-(3), generation module 212 may preserve boundary precision and corner information that may otherwise be lost with a single channel image.

In one example, generation module 212 may generate set of antenna designs 206 by further clipping dimensions beyond a boundary of a printed circuit board and by combining overlapping generated patches of substrate representing the antenna geometry using image masking. In some examples, the term “image masking” may refer to an image editing technique to isolate specific areas of an image for editing. In these examples, generation module 212 may use image masking to combine overlapping rectangular patches into a non-rectangular shape, such as patches 306 of FIG. 3. In these examples, combining the overlapping patches may ensure the patches do not increase in thickness in the overlapping sections. In other examples, generation module 212 may generate set of antenna designs 206 using other types of geometry or design methods to shape unique antennas.

In some embodiments, generation module 212 may generate set of antenna designs 206 by further augmenting the image representation of each antenna design with two additional channels of linear coordinates. In these embodiments, augmenting image representations with additional channels of x and y coordinates may ensure details of the specific antenna shape and location are preserved to more accurately calculate resonance characteristics. In additional embodiments, generation module 212 may use additional dimensions, such as with 3D representations, or other image data to represent antenna designs. For example, antenna design 208 may include color channels, such as red, green, and blue (RGB) channels, and/or other types of channel divisions to better capture details.

In one example, machine-learning model 204 of FIG. 2 may include one or more convolutional neural networks (CNNs) that process set of antenna designs 206 to generate feature maps. In some examples, the term “convolution” may refer to a method of modifying a sequence in order to condense the size and complexity of the data. In some examples, the term “convolutional neural network” may refer to a type of neural network that extracts and learns from features of data, particularly image data. In some examples, the term “feature” may refer to a value or vector derived from data that enables it to be measured and/or interpreted as part of a machine learning method. Specifically, a convolutional neural network may generate a feature map, which may include patterns derived from image data after applying various filters during convolution. In the example of FIG. 4, antenna design 208 including channels 302(1)-(3) may represent input to a CNN 402, which may then output a feature map 404. Although illustrated as a single feature map in FIG. 4, feature map 404 may represent a set of feature maps for antenna design 208. In some examples, by dividing the image representation of antenna design 208 into separate channels, generation module 212 may ensure that CNN 402 can more quickly learn the important features of antenna design 208. Additionally, a number of layers in a neural network model, such as CNN 402, may be adjusted to reduce biases due to limited data. In some examples, the term “layer” may refer to a portion of a neural network or deep learning model that takes input from a previous layer and outputs to the next layer. For example, a model with more layers, or a deeper model, may learn more detailed information about the input data, while a shallower model may process data faster through fewer layers.

Returning to FIG. 1, at step 120, one or more of the systems described herein may tokenize, by the computing device, each antenna design in the generated set of antenna designs. For example, a tokenizer module 214 may, as part of computing device 202 of FIG. 2, tokenize each of antenna designs 208(1)-(3) in set of antenna designs 206.

The systems described herein may perform step 120 in a variety of ways. In some examples, the term “tokenize” may refer to a process of converting unstructured data into units of discrete elements, or tokens. In one example, tokenizer module 214 may tokenize each antenna design by generating a set of visual tokens for an antenna design by mapping each pixel of the feature maps via pointwise convolution. Additionally, tokenizer module may apply a softmax function to the set of visual tokens. In these examples, tokenizer module 214 may apply spatial attention techniques to set of antenna designs 206 to create visual tokens. In some examples, the term “spatial attention” may refer to a technique for analyzing images by selectively processing visual information by prioritizing areas of focus through neural network modeling. In some examples, the term “pointwise convolution” may refer to a type of convolution that iterates through every point, or pixel, for each channel of an image. In some examples, the term “softmax function” may refer to a function of a neural network that normalizes the output of the neural network over a probability distribution.

As illustrated in FIG. 5, tokenizer module 214 of FIG. 2 may process each of pixels 502(1)-(N) of feature map 404, which represents antenna design 208 of FIG. 4, by performing a pointwise convolution 504 to create a set of visual tokens 506. In this example, a softmax function 510 may then normalize the output for each of visual tokens 508(1)-(M) to create the final set of tokens.

Returning to FIG. 1, at step 130, one or more of the systems described herein may predict, by the machine-learning model of the computing device, a frequency response for each tokenized antenna design. For example, a prediction module 216 may, as part of computing device 202 of FIG. 2, predict frequency responses 210(1)-(3) for tokenized antenna designs 208(1)-(3).

The systems described herein may perform step 130 in a variety of ways. In some embodiments, prediction module 216 may predict frequency responses 210(1)-(3) by transforming the set of visual tokens using a transformer-based encoder, flattening an output of the transformer-based encoder, and passing the flattened output through a fully-connected (FC) layer of machine-learning model 204. In some examples, the term “transformer” may refer to a type of neural network architecture used in machine learning to learn context from sequential data. In these examples, the term “transformer-based encoder” may refer to one or more encoder layers that process tokens as input and transform them into vectors. Similarly, in some examples, the term “flatten” may refer to a process of converting matrices of features into vectors. In some examples, the term “fully-connected layer” may refer to a neural network layer that connects each node of a current layer to every node of a previous layer, thereby fully connecting each layer. In these examples, the transformer-based encoder and the flattening process may ensure the set of visual tokens are transformed into vectors before further processing data through the FC layer. In these embodiments, local characteristics and spatial components of an antenna may be easier to calculate than global characteristics. In these embodiments, the transformer-based encoder may be used to calculate global characteristics of an antenna from local data. For example, local components such as boundaries between areas of an antenna may be tokenized and used by the transformer-based encoder to compute global characteristics for the entire antenna.

In the above embodiments, prediction module 216 may then predict, based on the output of the FC layer, a set of global characteristics for a scattering matrix function and calculate frequency responses 210(1)-(3) for each tokenized antenna design based on the set of global characteristics. In some examples, the term “scattering matrix” may refer to a matrix describing different states of scattering, such as for an antenna signal, over time. In these embodiments, the set of global characteristics may include one or more constants of the scattering matrix function, one or more zeros of the scattering matrix function, and/or one or more poles of the scattering matrix function. In some examples, the term “constant” may refer to a mathematical constant with a fixed value. In some examples, the term “zero” may refer to an input value for a function that produces an output of 0. In some examples, the term “pole” may refer to the input value for a function that is equivalent to the zero of an inverse of the function. In these examples, the FC layer may determine the zeros and poles for the scattering matrix function of a specific antenna design.

In the example of FIG. 4, feature map 404 may first be processed by tokenizer module 214, and the resulting tokens may then be processed by prediction module 216. In this example, prediction module 216 then predicts a frequency response 210 for antenna design 208. FIG. 6 illustrates the prediction process in more detail. As illustrated in FIG. 6, after passing through a transformer-based encoder 602, set of visual tokens 506 may be flattened into a flattened output 604 to create vectors representing antenna design 208 of FIG. 4. In this example, flattened output 604 is then input into a fully-connected layer 606, which may then predict a set of global characteristics 608 for antenna design 208. In this example, set of global characteristics 608 may include a constant 610, which may represent at least one mathematical constant of a scattering matrix function 616. Additionally, set of global characteristics 608 may include zeros 612(1)-(2) and poles 614(1)-(2). In other examples, prediction module 216 may predict additional zeros and poles to as part of set of global characteristics 608 and/or additional constants. In some examples, fully-connected layer 606 may represent three separate complex-valued FC layers that predict set of global characteristics 608, which is then used to calculate frequency response 210. By inputting set of global characteristics 608 into scattering matrix function 616, prediction module 216 may then complete scattering matrix function 616 to obtain a value or a range of values for frequency response 210. For example, prediction module 216 may calculate an S11 scattering matrix, wherein S11 may be considered a reflection coefficient indicating how much power is reflected from an antenna, thereby being lost.

Returning to FIG. 1, at step 140, one or more of the systems described herein may compare, by the computing device, the frequency response for each tokenized antenna design. For example, a comparison module 218 may, as part of computing device 202 of FIG. 2, compare frequency responses 210(1)-(3).

The systems described herein may perform step 140 in a variety of ways. In some examples, comparison module 218 may compare frequency responses 210(1)-(3) to identify the antenna design with the widest range of frequency sensitivity. By automating the generation and testing of set of antenna designs 206, system 200 of FIG. 2 may use frequency responses 210(1)-(3) to identify acceptable antenna designs and/or to rank antenna designs 208(1)-(3) based on sensitivity.

Returning to FIG. 1, at step 150, one or more of the systems described herein may select, by the computing device based on the comparison, an antenna design that meets a performance threshold for the frequency response. For example, a selection module 220 may, as part of computing device 202 of FIG. 2, select antenna design 208(1) that meets a performance threshold 222 for frequency response 210(1).

The systems described herein may perform step 150 in a variety of ways. In some examples, performance threshold 222 may represent a target range of frequencies that antenna design 208(1) must be able to detect and/or broadcast. In other words, selection module 220 may select a design that best fits gain and/or loss parameters for a preferred signal frequency range. To meet frequency constraints for an antenna, the antenna's gain may be less than a specific threshold, such as a specific decibel (dB) threshold. Based on comparison module 218 comparing and/or ranking frequency responses 210(1)-(3) of set of antenna designs 206, selection module 220 may then use performance threshold 222 to narrow down designs that fulfill the parameters for a particular use or device, resulting in the selection of antenna design 208(1) as the most fitting design.

In some examples, the disclosed systems and methods may further include retraining machine-learning model 204 with set of antenna designs 206 and predicted frequency responses 210(1)-(3) for each tokenized antenna design. In these examples, pairs of antenna designs 208(1)-(3) and frequency responses 210(1)-(3) may be used to improve the training of machine-learning model 204 to generate better antenna designs that fulfill specified requirements. In some embodiments, the disclosed systems and methods may further verify the selection of antenna design 208(1) using simulator software, such as commercial electromagnetic modeling software. In these embodiments, the verification may improve the use of antenna design 208(1) to retrain machine-learning model 204. In some embodiments, machine-learning model 204 may generate a large number of antenna designs and use a majority of the designs for training, with the remaining used for testing and validation. By continuously improving machine-learning model 204, the disclosed systems and methods may also iteratively improve the design of antennas to quickly design and identify an antenna design that meets frequency response requirements. In further embodiments, the disclosed systems and methods may be applied to other forms of design to derive frequency responses.

As explained above in connection with method 100 in FIG. 1, the disclosed systems and methods may, by using machine-learning methods to generate and test antenna designs, increase the speed and likelihood of creating an antenna that fulfills necessary requirements. Specifically, a surrogate machine-learning model may first generate image representations of antenna geometry, inspired by mesh-based simulation, to create a set of antenna designs. The disclosed systems and methods may then transform each antenna design into a multi-channel image representation. The surrogate machine-learning model may also model network architecture that leverages a transformer-based encoder to handle non-linear relationships of antenna topology and resonances. For example, the disclosed systems and methods may tokenize the image representations to predict complex-valued zeros and poles of an S11 scattering matrix, which may then be used to compute the frequency responses of antenna designs. Furthermore, the disclosed systems and methods may incorporate domain-specific inductive biases to deal with issues from limited data. For example, the disclosed systems and methods may focus on the boundaries of an antenna design and use neural network models to focus on constants, zeros, and poles in predicting frequency responses.

The disclosed systems and methods may also be sample efficient, using multi-channel image representations to capture critical boundary information usually captured by high-resolution meshes. By using a data-driven surrogate model, the disclosed systems and methods may create simulations in parallel, instead of sequentially, to save on modeling time. Additionally, the S11 scattering matrix, which relates material properties to an antenna's resonance characteristics, may represent the ratio of complex-valued polynomials with a compact representation of constants, zeros, and poles, thereby improving the speed of calculating frequency responses. The disclosed systems and methods may also be used in conjunction with existing antenna design methods, such as by using simulation software to verify design results and improve the surrogate machine-learning model. Thus, the systems and methods described herein may improve over traditional methods of antenna design and simulation by creating an improved antenna design process that uses machine-learning methods to generate image representations of antennas and perform faster testing with a transformer-based model.

Example 1: A computer-implemented method for antenna design may include 1) generating, using a machine-learning model of a computing device, a set of antenna designs, 2) tokenizing, by the computing device, each antenna design in the generated set of antenna designs, 3) predicting, by the machine-learning model of the computing device, a frequency response for each tokenized antenna design, 4) comparing, by the computing device, the frequency response for each tokenized antenna design, and 5) selecting, by the computing device based on the comparison, an antenna design that meets a performance threshold for the frequency response.

Example 2: The computer-implemented method of Example 1, wherein the set of antenna designs may include, for each antenna design, an image representation of antenna geometry comprising three channels.

Example 3: The computer-implemented method of Example 2, wherein the three channels may include a representation of boundary values for a first dimension, a representation of boundary values for a second dimension, and a binary image representation of an interior of the antenna geometry.

Example 4: The computer-implemented method of any of Examples 2-3, wherein generating the set of antenna designs may further include clipping dimensions beyond a boundary of a printed circuit board and combining overlapping generated patches of substrate representing the antenna geometry using image masking.

Example 5: The computer-implemented method of any of Examples 2-4, wherein generating the set of antenna designs may further include augmenting the image representation with two additional channels of linear coordinates.

Example 6: The computer-implemented method of any of Examples 1-5, wherein the machine-learning model may include one or more convolutional neural networks that processes the set of antenna designs to generate feature maps.

Example 7: The computer-implemented method of Example 6, wherein tokenizing each antenna design may include generating a set of visual tokens for an antenna design by mapping each pixel of the feature maps via pointwise convolution and applying a softmax function to the set of visual tokens.

Example 8: The computer-implemented method of Example 7, wherein predicting the frequency response for each tokenized antenna design may include 1) transforming the set of visual tokens using a transformer-based encoder, 2) flattening an output of the transformer-based encoder, 3) passing the flattened output through a fully-connected layer of the machine-learning model, 4) predicting, based on the output of the fully-connected layer, a set of global characteristics for a scattering matrix function, and 5) calculating the frequency response for each tokenized antenna design based on the set of global characteristics.

Example 9: The computer-implemented method of Example 8, wherein the set of global characteristics may include one or more of a constant of the scattering matrix function, a zero of the scattering matrix function, and/or a pole of the scattering matrix function.

Example 10: The computer-implemented method of any of Examples 1-9 may further include retraining the machine-learning model with the set of antenna designs and the predicted frequency response for each tokenized antenna design.

Example 11: A corresponding system for antenna design may include several modules store in memory, including 1) a generation module that generates, using a machine-learning model, a set of antenna designs, 2) a tokenizer module that tokenizes each antenna design in the generated set of antenna designs, 3) a prediction module that predicts, by the machine-learning model, a frequency response for each tokenized antenna design, 4) a comparison module that compares the frequency response for each tokenized antenna design, and 5) a selection module that selects, based on the comparison, an antenna design that meets a performance threshold for the frequency response. The system may also include one or more hardware processors that execute the generation module, the tokenizer module, the prediction module, the comparison module, and the selection module.

Example 12: The system of Example 11, wherein the set of antenna designs may include, for each antenna design, an image representation of antenna geometry comprising three channels.

Example 13: The system of Example 12, wherein the three channels may include a representation of boundary values for a first dimension, a representation of boundary values for a second dimension, and a binary image representation of an interior of the antenna geometry.

Example 14: The system of any of Examples 12-13, wherein the generation module may generate the set of antenna designs by further clipping dimensions beyond a boundary of a printed circuit board and combining overlapping generated patches of substrate representing the antenna geometry using image masking.

Example 15: The system of any of Examples 12-14, wherein the generation module may generate the set of antenna designs by further augmenting the image representation with two additional channels of linear coordinates.

Example 16: The system of any of Examples 11-15, wherein the machine-learning model may include one or more convolutional neural networks that process the set of antenna designs to generate feature maps.

Example 17: The system of Example 16, wherein the tokenizer module may tokenize each antenna design by generating a set of visual tokens for an antenna design by mapping each pixel of the feature maps via pointwise convolution and applying a softmax function to the set of visual tokens.

Example 18: The system of Example 17, wherein the prediction module may predict the frequency response for each tokenized antenna design by 1) transforming the set of visual tokens using a transformer-based encoder, 2) flattening an output of the transformer-based encoder, 3) passing the flattened output through a fully-connected layer of the machine-learning model, 4) predicting, based on the output of the fully-connected layer, a set of global characteristics for a scattering matrix function, and 5) calculating the frequency response for each tokenized antenna design based on the set of global characteristics.

Example 19: The system of Example 18, wherein the set of global characteristics may include one or more of a constant of the scattering matrix function, a zero of the scattering matrix function, and a pole of the scattering matrix function.

Example 20: The above-described method may be encoded as computer-readable instructions on a computer-readable medium. For example, a non-transitory computer-readable medium may include one or more computer-executable instructions that, when executed by one or more processors of a computing device, may cause the computing device to 1) generate, using a machine-learning model of the computing device, a set of antenna designs, 2) tokenize each antenna design in the generated set of antenna designs, 3) predict, by the machine-learning model, a frequency response for each tokenized antenna design, 4) compare the frequency response for each tokenized antenna design, and 5) select, based on the comparison, an antenna design that meets a performance threshold for the frequency response.

Embodiments of the present disclosure may include or be implemented in-conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 700 in FIG. 7) or that visually immerses a user in an artificial reality (such as, e.g., virtual-reality system 800 in FIG. 8). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 7, augmented-reality system 700 may include an eyewear device 702 with a frame 710 configured to hold a left display device 715(A) and a right display device 715(B) in front of a user's eyes. Display devices 715(A) and 715(B) may act together or independently to present an image or series of images to a user. While augmented-reality system 700 includes two displays, embodiments of this disclosure may be implemented in augmented-reality systems with a single NED or more than two NEDs.

In some embodiments, augmented-reality system 700 may include one or more sensors, such as sensor 740. Sensor 740 may generate measurement signals in response to motion of augmented-reality system 700 and may be located on substantially any portion of frame 710. Sensor 740 may represent one or more of a variety of different sensing mechanisms, such as a position sensor, an inertial measurement unit (IMU), a depth camera assembly, a structured light emitter and/or detector, or any combination thereof. In some embodiments, augmented-reality system 700 may or may not include sensor 740 or may include more than one sensor. In embodiments in which sensor 740 includes an IMU, the IMU may generate calibration data based on measurement signals from sensor 740. Examples of sensor 740 may include, without limitation, accelerometers, gyroscopes, magnetometers, other suitable types of sensors that detect motion, sensors used for error correction of the IMU, or some combination thereof.

In some examples, augmented-reality system 700 may also include a microphone array with a plurality of acoustic transducers 720(A)-720(J), referred to collectively as acoustic transducers 720. Acoustic transducers 720 may represent transducers that detect air pressure variations induced by sound waves. Each acoustic transducer 720 may be configured to detect sound and convert the detected sound into an electronic format (e.g., an analog or digital format). The microphone array in FIG. 7 may include, for example, ten acoustic transducers: 720(A) and 720(B), which may be designed to be placed inside a corresponding ear of the user, acoustic transducers 720(C), 720(D), 720(E), 720(F), 720(G), and 720(H), which may be positioned at various locations on frame 710, and/or acoustic transducers 720(I) and 720(J), which may be positioned on a corresponding neckband 705.

In some embodiments, one or more of acoustic transducers 720(A)-(J) may be used as output transducers (e.g., speakers). For example, acoustic transducers 720(A) and/or 720(B) may be earbuds or any other suitable type of headphone or speaker.

The configuration of acoustic transducers 720 of the microphone array may vary. While augmented-reality system 700 is shown in FIG. 7 as having ten acoustic transducers 720, the number of acoustic transducers 720 may be greater or less than ten. In some embodiments, using higher numbers of acoustic transducers 720 may increase the amount of audio information collected and/or the sensitivity and accuracy of the audio information. In contrast, using a lower number of acoustic transducers 720 may decrease the computing power required by an associated controller 750 to process the collected audio information. In addition, the position of each acoustic transducer 720 of the microphone array may vary. For example, the position of an acoustic transducer 720 may include a defined position on the user, a defined coordinate on frame 710, an orientation associated with each acoustic transducer 720, or some combination thereof.

Acoustic transducers 720(A) and 720(B) may be positioned on different parts of the user's ear, such as behind the pinna, behind the tragus, and/or within the auricle or fossa. Or, there may be additional acoustic transducers 720 on or surrounding the ear in addition to acoustic transducers 720 inside the ear canal. Having an acoustic transducer 720 positioned next to an ear canal of a user may enable the microphone array to collect information on how sounds arrive at the ear canal. By positioning at least two of acoustic transducers 720 on either side of a user's head (e.g., as binaural microphones), augmented-reality system 700 may simulate binaural hearing and capture a 3D stereo sound field around about a user's head. In some embodiments, acoustic transducers 720(A) and 720(B) may be connected to augmented-reality system 700 via a wired connection 730, and in other embodiments acoustic transducers 720(A) and 720(B) may be connected to augmented-reality system 700 via a wireless connection (e.g., a BLUETOOTH connection). In still other embodiments, acoustic transducers 720(A) and 720(B) may not be used at all in conjunction with augmented-reality system 700.

Acoustic transducers 720 on frame 710 may be positioned in a variety of different ways, including along the length of the temples, across the bridge, above or below display devices 715(A) and 715(B), or some combination thereof. Acoustic transducers 720 may also be oriented such that the microphone array is able to detect sounds in a wide range of directions surrounding the user wearing the augmented-reality system 700. In some embodiments, an optimization process may be performed during manufacturing of augmented-reality system 700 to determine relative positioning of each acoustic transducer 720 in the microphone array.

In some examples, augmented-reality system 700 may include or be connected to an external device (e.g., a paired device), such as neckband 705. Neckband 705 generally represents any type or form of paired device. Thus, the following discussion of neckband 705 may also apply to various other paired devices, such as charging cases, smart watches, smart phones, wrist bands, other wearable devices, hand-held controllers, tablet computers, laptop computers, other external compute devices, etc.

As shown, neckband 705 may be coupled to eyewear device 702 via one or more connectors. The connectors may be wired or wireless and may include electrical and/or non-electrical (e.g., structural) components. In some cases, eyewear device 702 and neckband 705 may operate independently without any wired or wireless connection between them. While FIG. 7 illustrates the components of eyewear device 702 and neckband 705 in example locations on eyewear device 702 and neckband 705, the components may be located elsewhere and/or distributed differently on eyewear device 702 and/or neckband 705. In some embodiments, the components of eyewear device 702 and neckband 705 may be located on one or more additional peripheral devices paired with eyewear device 702, neckband 705, or some combination thereof.

Pairing external devices, such as neckband 705, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 700 may be provided by a paired device or shared between a paired device and an eyewear device, thus reducing the weight, heat profile, and form factor of the eyewear device overall while still retaining desired functionality. For example, neckband 705 may allow components that would otherwise be included on an eyewear device to be included in neckband 705 since users may tolerate a heavier weight load on their shoulders than they would tolerate on their heads. Neckband 705 may also have a larger surface area over which to diffuse and disperse heat to the ambient environment. Thus, neckband 705 may allow for greater battery and computation capacity than might otherwise have been possible on a stand-alone eyewear device. Since weight carried in neckband 705 may be less invasive to a user than weight carried in eyewear device 702, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 705 may be communicatively coupled with eyewear device 702 and/or to other devices. These other devices may provide certain functions (e.g., tracking, localizing, depth mapping, processing, storage, etc.) to augmented-reality system 700. In the embodiment of FIG. 7, neckband 705 may include two acoustic transducers (e.g., 720(I) and 720(J)) that are part of the microphone array (or potentially form their own microphone subarray). Neckband 705 may also include a controller 725 and a power source 735.

Acoustic transducers 720(I) and 720(J) of neckband 705 may be configured to detect sound and convert the detected sound into an electronic format (analog or digital). In the embodiment of FIG. 7, acoustic transducers 720(I) and 720(J) may be positioned on neckband 705, thereby increasing the distance between the neckband acoustic transducers 720(I) and 720(J) and other acoustic transducers 720 positioned on eyewear device 702. In some cases, increasing the distance between acoustic transducers 720 of the microphone array may improve the accuracy of beamforming performed via the microphone array. For example, if a sound is detected by acoustic transducers 720(C) and 720(D) and the distance between acoustic transducers 720(C) and 720(D) is greater than, e.g., the distance between acoustic transducers 720(D) and 720(E), the determined source location of the detected sound may be more accurate than if the sound had been detected by acoustic transducers 720(D) and 720(E).

Controller 725 of neckband 705 may process information generated by the sensors on neckband 705 and/or augmented-reality system 700. For example, controller 725 may process information from the microphone array that describes sounds detected by the microphone array. For each detected sound, controller 725 may perform a direction-of-arrival (DOA) estimation to estimate a direction from which the detected sound arrived at the microphone array. As the microphone array detects sounds, controller 725 may populate an audio data set with the information. In embodiments in which augmented-reality system 700 includes an inertial measurement unit, controller 725 may compute all inertial and spatial calculations from the IMU located on eyewear device 702. A connector may convey information between augmented-reality system 700 and neckband 705 and between augmented-reality system 700 and controller 725. The information may be in the form of optical data, electrical data, wireless data, or any other transmittable data form. Moving the processing of information generated by augmented-reality system 700 to neckband 705 may reduce weight and heat in eyewear device 702, making it more comfortable to the user.

Power source 735 in neckband 705 may provide power to eyewear device 702 and/or to neckband 705. Power source 735 may include, without limitation, lithium ion batteries, lithium-polymer batteries, primary lithium batteries, alkaline batteries, or any other form of power storage. In some cases, power source 735 may be a wired power source. Including power source 735 on neckband 705 instead of on eyewear device 702 may help better distribute the weight and heat generated by power source 735.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 800 in FIG. 8, that mostly or completely covers a user's field of view. Virtual-reality system 800 may include a front rigid body 802 and a band 804 shaped to fit around a user's head. Virtual-reality system 800 may also include output audio transducers 806(A) and 806(B). Furthermore, while not shown in FIG. 8, front rigid body 802 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 700 and/or virtual-reality system 800 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 700 and/or virtual-reality system 800 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 700 and/or virtual-reality system 800 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

As detailed above, the computing devices and systems described and/or illustrated herein broadly represent any type or form of computing device or system capable of executing computer-readable instructions, such as those contained within the modules described herein. In their most basic configuration, these computing device(s) may each include at least one memory device and at least one physical processor.

In some examples, the term “memory device” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In some examples, the term “physical processor” generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. For example, one or more of the modules recited herein may receive an antenna design to be transformed, transform the antenna design into an image representation, output a result of the transformation to tokenize the antenna design, use the result of the transformation to calculate a frequency response, and store the result of the transformation to compare and select a design. Additionally or alternatively, one or more of the modules recited herein may transform a processor, volatile memory, non-volatile memory, and/or any other portion of a physical computing device from one form to another by executing on the computing device, storing data on the computing device, and/or otherwise interacting with the computing device.

In some embodiments, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A computer-implemented method comprising:
generating, using a machine-learning model of a computing device, a set of antenna designs;
tokenizing, by the computing device, each antenna design in the generated set of antenna designs;
predicting, by the machine-learning model of the computing device, a frequency response for each tokenized antenna design;
comparing, by the computing device, the frequency response for each tokenized antenna design; and
selecting, by the computing device based on the comparison, an antenna design that meets a performance threshold for the frequency response.

2. The method of claim 1, wherein the set of antenna designs comprises, for each antenna design, an image representation of antenna geometry comprising three channels.

3. The method of claim 2, wherein the three channels comprise:
a representation of boundary values for a first dimension;
a representation of boundary values for a second dimension; and
a binary image representation of an interior of the antenna geometry.

4. The method of claim 2, wherein generating the set of antenna designs further comprises:
clipping dimensions beyond a boundary of a printed circuit board; and
combining overlapping generated patches of substrate representing the antenna geometry using image masking.

5. The method of claim 2, wherein generating the set of antenna designs further comprises augmenting the image representation with two additional channels of linear coordinates.

6. The method of claim 1, wherein the machine-learning model comprises at least one convolutional neural network that processes the set of antenna designs to generate feature maps.

7. The method of claim 6, wherein tokenizing each antenna design comprises:
generating a set of visual tokens for an antenna design by mapping each pixel of the feature maps via pointwise convolution; and
applying a softmax function to the set of visual tokens.

8. The method of claim 7, wherein predicting the frequency response for each tokenized antenna design comprises:
transforming the set of visual tokens using a transformer-based encoder;
flattening an output of the transformer-based encoder;
passing the flattened output through a fully-connected layer of the machine-learning model;
predicting, based on the output of the fully-connected layer, a set of global characteristics for a scattering matrix function; and
calculating the frequency response for each tokenized antenna design based on the set of global characteristics.

9. The method of claim 8, wherein the set of global characteristics comprises at least one of:
a constant of the scattering matrix function;
a zero of the scattering matrix function; and
a pole of the scattering matrix function.

10. The method of claim 1, further comprising retraining the machine-learning model with the set of antenna designs and the predicted frequency response for each tokenized antenna design.

11. A system comprising:
a generation module, stored in memory, that generates, using a machine-learning model, a set of antenna designs;
a tokenizer module, stored in memory, that tokenizes each antenna design in the generated set of antenna designs;
a prediction module, stored in memory, that predicts, by the machine-learning model, a frequency response for each tokenized antenna design;
a comparison module, stored in memory, that compares the frequency response for each tokenized antenna design;
a selection module, stored in memory, that selects, based on the comparison, an antenna design that meets a performance threshold for the frequency response; and
at least one processor that executes the generation module, the tokenizer module, the prediction module, the comparison module, and the selection module.

12. The system of claim 11, wherein the set of antenna designs comprises, for each antenna design, an image representation of antenna geometry comprising three channels.

13. The system of claim 12, wherein the three channels comprise:
a representation of boundary values for a first dimension;
a representation of boundary values for a second dimension; and
a binary image representation of an interior of the antenna geometry.

14. The system of claim 12, wherein the generation module generates the set of antenna designs by further:
clipping dimensions beyond a boundary of a printed circuit board; and
combining overlapping generated patches of substrate representing the antenna geometry using image masking.

15. The system of claim 12, wherein the generation module generates the set of antenna designs by further augmenting the image representation with two additional channels of linear coordinates.

16. The system of claim 11, wherein the machine-learning model comprises at least one convolutional neural network that processes the set of antenna designs to generate feature maps.

17. The system of claim 16, wherein the tokenizer module tokenizes each antenna design by:
generating a set of visual tokens for an antenna design by mapping each pixel of the feature maps via pointwise convolution; and
applying a softmax function to the set of visual tokens.

18. The system of claim 17, wherein the prediction module predicts the frequency response for each tokenized antenna design by:
transforming the set of visual tokens using a transformer-based encoder;
flattening an output of the transformer-based encoder;
passing the flattened output through a fully-connected layer of the machine-learning model;
predicting, based on the output of the fully-connected layer, a set of global characteristics for a scattering matrix function; and
calculating the frequency response for each tokenized antenna design based on the set of global characteristics.

19. The system of claim 18, wherein the set of global characteristics comprises at least one of:
a constant of the scattering matrix function;
a zero of the scattering matrix function; and
a pole of the scattering matrix function.

20. A non-transitory computer-readable medium comprising one or more computer-executable instructions that, when executed by at least one processor of a computing device, cause the computing device to:
generate, using a machine-learning model of the computing device, a set of antenna designs;
tokenize, by the computing device, each antenna design in the generated set of antenna designs;
predict, by the machine-learning model of the computing device, a frequency response for each tokenized antenna design;
compare, by the computing device, the frequency response for each tokenized antenna design; and
select, by the computing device based on the comparison, an antenna design that meets a performance threshold for the frequency response.
